(19) United States
(12) Patent Application Publication
(10) Pub. No.: US 2025/0040048 A1
(43) Pub. Date: Jan. 30, 2025

(54) Portable communication relay

(71) Applicant: Red Line Safety, Inc., Greenwood, CA (US)

(72) Inventors: David Scott Holman, Greenwood, CA (US); David McGillicuddy, Cool, CA (US); Sashi Ono, Santa Barbara, CA (US); David Lujan, Lahaini, HI (US)

(73) Assignee: Red Line Safety, Inc., Greenwood, CA (US)

(21) Appl. No.: 18/831,092

(22) Filed: Jul. 5, 2024

Related U.S. Application Data
(60) Provisional application No. 63/628,382, filed on Jul. 14, 2023.

(51) Int. Cl. H05K 1/14; G08B 25/00

(52) U.S. Cl. CPC H05K 1/14; G08B 25/009; H05K 2201/10151

(57) ABSTRACT

The present invention is generally directed to methods, systems and devices for communication of information related to emergency situations. In one aspect, the present invention provides a system for communication of information related to emergency situations. The system comprises a first printed circuit board, a second printed circuit board and a third printed circuit board. The first printed circuit board, the second printed circuit board and the third printed circuit board plug into each other to form a communication relay. The first printed circuit board is a communication platform comprising GPS, Cellular, a CO₂ sensor, an Air Temp sensor and LoraWan. The second printed circuit board is a weather station comprising humidity and barometric pressure sensors. The third printed circuit board is a wind sensor comprising ultrasonic wind sensors.

### CROSS-REFERENCE TO RELATED APPLICATION

This application claims the benefit of U.S. Provisional Patent Application No. 63/628,382, filed Jul. 14, 2023, which is incorporated by reference herein in its entirety.

### FIELD OF THE INVENTION

The present invention is generally directed to methods, systems and devices for communication of information related to emergency situations.

### BACKGROUND OF THE INVENTION

There have been reports related to methods and systems related to emergency situations. For instance, US2023127315 entitled, “Wearable Emergency Alert Systems and Related Methods” alleges the following in its disclosure: “A method of sending an emergency alert from a wearable device. The wearable device is connected to a low-power wide area cellular network and to global positioning services as soon as it is turned on. The wearable device receives inputs from the user and/or from at least one sensor located within the wearable device measuring parameters associated with the status of the user. A determination is then made if an emergency situation has occurred, if so, an emergency alert is transmitted to recipients based on a configured set of emergency contacts. The determining of an emergency condition occurs based on the inputs received through the wearable device or by the inputs received by the at least one sensor corresponding with a set of rules established for determining if an emergency alert should be sent.” Abstract.

US2023130719 entitled, “Cyber-Physical Integrated Restoration Method and System for Distribution Systems Based on Emergency Mobil Communications” reports: “A cyber-physical integrated restoration method and system for distribution systems based on emergency mobile communications are provided. After extreme natural disasters which cause serious damage to distribution systems, damages of distribution systems are evaluated through system feedback data. When ground communication base stations are unavailable due to the damages, the method can make full use of existing wireless emergency communication resources to provide emergency communication services, a quickly restore the power supply through distribution automation functions with supports of the backup battery of automatic terminal devices, so as to effectively improve the resilience of distribution systems.” Abstract.

CA3191254 entitled, “Emergency Communication System” discusses the following: “The present invention relates to a method for providing an emergency communications. The method includes the steps of: a central server obtaining information from at least some of a plurality of users prior to an emergency during an event; and during an emergency, the central server coordinating communications between at least some of the plurality of users via a plurality of user devices. The central server augments and/or coordinates communications using the information previously provided by the at least some of the plurality of users and at least one of the user devices is associated with emergency devices.” Abstract.

Despite the various reports, there is still a need for novel methods, systems and devices for communication of information related to emergency situations.

### SUMMARY OF THE INVENTION

In one aspect, the present invention provides a system for communication of information related to emergency situations. The system comprises a first printed circuit board, a second printed circuit board and a third printed circuit board. The first printed circuit board, the second printed circuit board and the third printed circuit board plug into each other to form a communication relay. The first printed circuit board is a communication platform comprising GPS, Cellular, a CO2 sensor, an Air Temp sensor and LoraWan. The second printed circuit board is a weather station comprising humidity and barometric pressure sensors. The third printed circuit board is a wind sensor comprising ultrasonic wind sensors.

### BRIEF DESCRIPTION OF THE DRAWINGS

FIG. 1 shows an outside view of the tracker, having the following labeled elements: LoraWan Antenna (1); Belt Clip (2); Vents (3); On/Off switch (4); USB-C Charging Port (5); and, a Function Button (6).

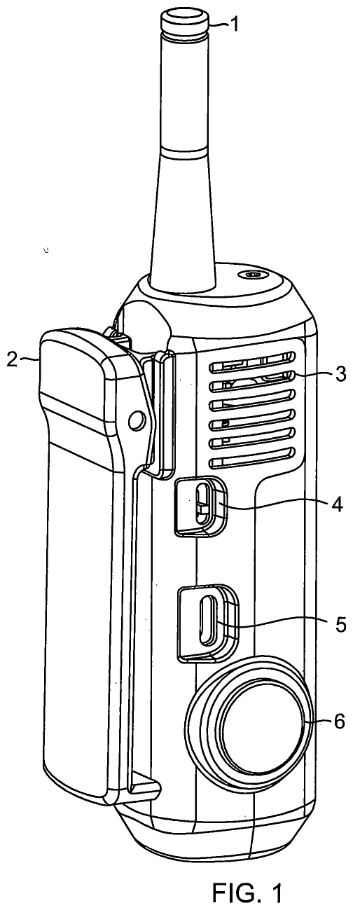

FIG. 2 shows a front side view of PCB #1, having the following labeled elements: Battery Tabs (7); LoraWan (8); USB-C Charging Port (5); On/Off Switch (4); Cellular NRF 9/60 (10); RF Antenna (11); Sim Card Holder (12); GPS (U12) (17); CO Sensor (14); Bluetooth/WiFi (15); LoraWan Antenna (1); Glonass GPS Chip (13).

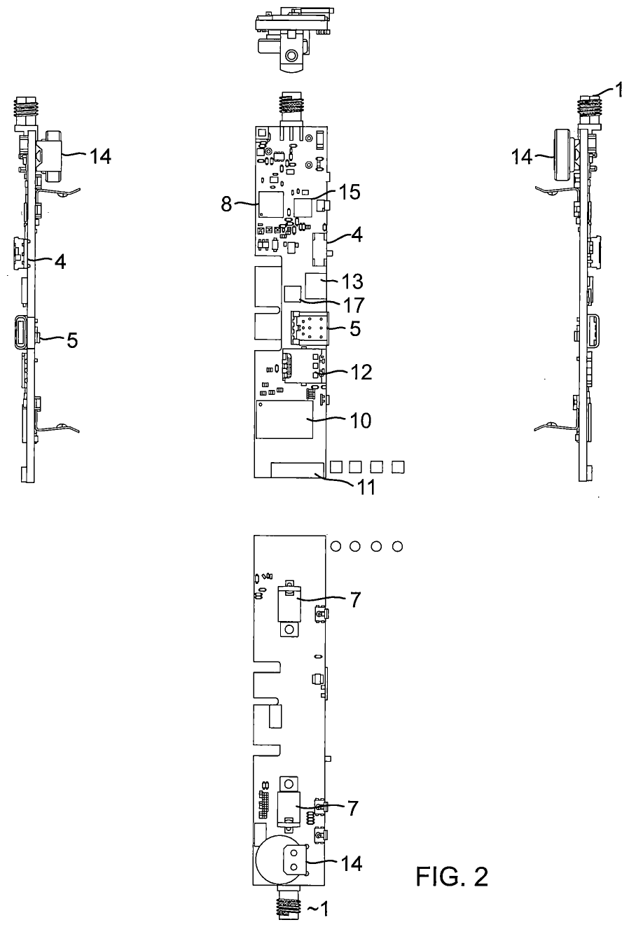

FIG. 3 shows a front side view of PCB #2, having the following labeled elements: GPS—NRF 9/60 (10); Dual 18650 Battery Holder (19); On/Off Switch (4); USB-C Charging Port (5); Thermal Camera Mounts (20); PM 2.5 Air Quality Sensor (21).

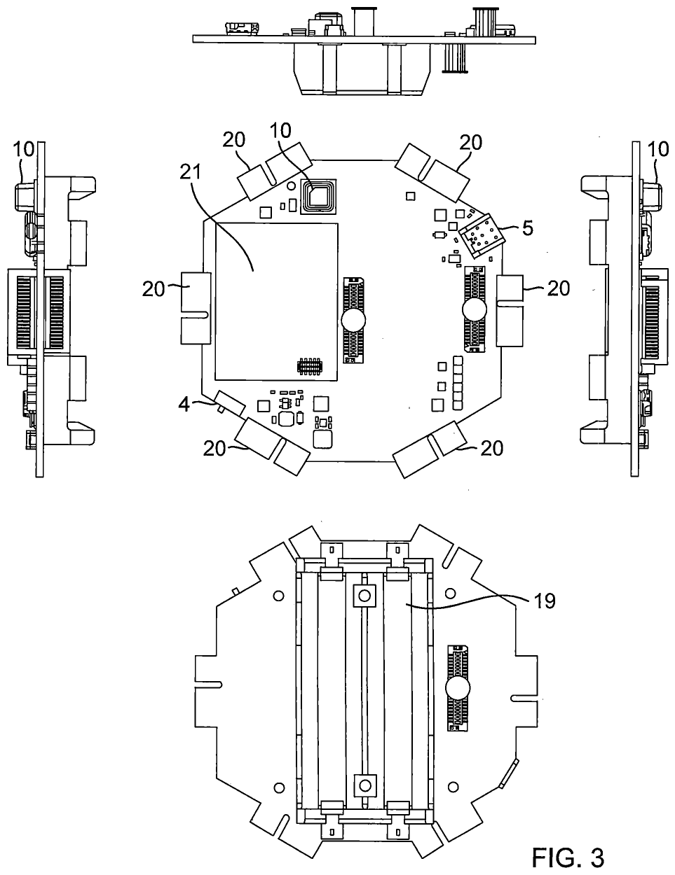

FIG. 4 shows a front side view of PCB #3, having the following labeled elements: NRF 9/60 (10); LoraWan (8); Ultrasonic Wind Sensors (22); LoraWan Antenna (1).

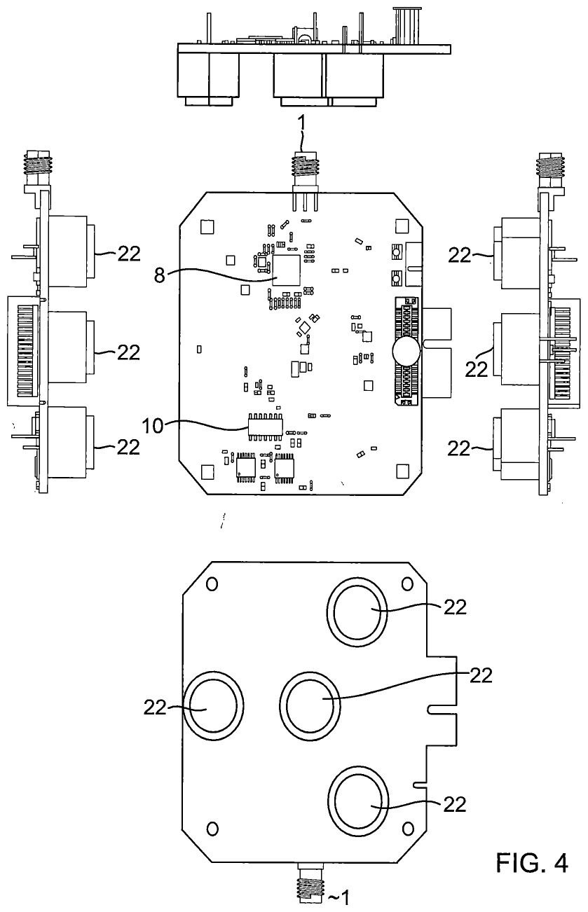

FIG. 5 shows a Gateway exploded view (without thermal cameras), having the following labeled elements: Air Vents (3); Antenna Mount (24); PCB #1 (25); PCB #2 (26); PCB #3 (27); Pole Mount (28); and, Wind Speed and Direction Chamber (29).

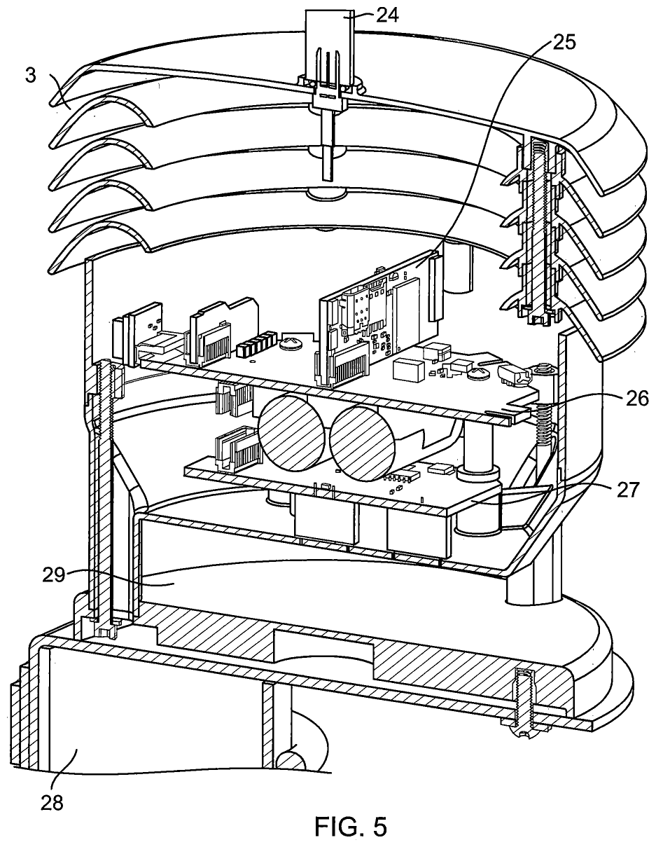

FIG. 6 shows the Gateway PCB configuration, having the following labeled elements: PCB #1 (25); PCB #2 (26); PCB #3 (27); 18650 Batteries (30); and, Ultrasonic Sensors (31).

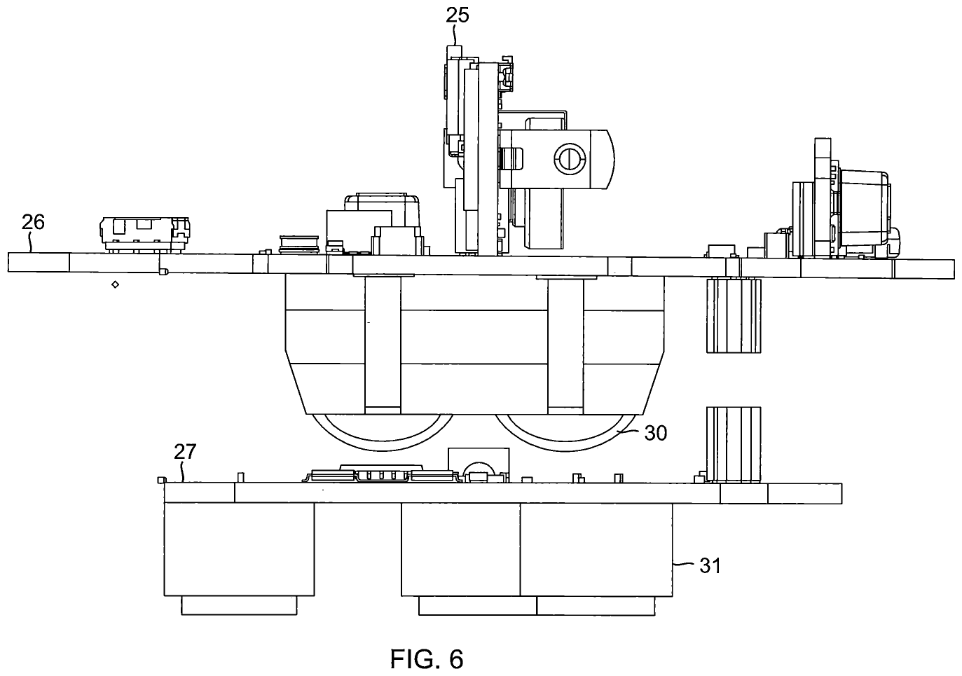

### DETAILED DESCRIPTION OF THE INVENTION

### Definitions

“Hub” refers to a cloud-based, full feature IoT wearable that collects and transmits data to the cloud via communication platforms. It can be used in all hazardous environments, for example—building fires, wildland first and hazardous material incidents. Hub features include, without limitation: GPS; Gyroscope; Accelerometer; Gas Sensors (CO, H2S, O2, TVOC); Atmospheric Sensors (Radiation, CO2); Thermal Camera; 3 Function Buttons; LCD Screen Display; Communication Platform (WiFi, Bluetooth, Cellular, LoRaWan); Water Proof; powered by an internal Lithium-Ion 18650, rechargeable battery; internal air pump that draws air through its water proof membrane on the back of the unit, across the sensors and exits through its one way valve on the bottom; LoRaWan Antenna.

“Tracker” refers to a modified version of the Hub that is primarily built for the wildland firefighter community. It is lighter, more compact and runs longer on its internal 18650 battery. The Tracker can be internally integrated into the communication gateway. Tracker features include, without limitation: GPS; Gyroscope; Accelerometer; Gas Sensors (CO, H2S, O2, TVOC); Atmospheric Sensors (Air Temp, Relative Humidity, Barometric Pressure); Thermal Camera; 1 Function Button; Communication Platform (WiFi, Bluetooth, Cellular, LoRaWan); powered by an internal Lithium-Ion 18650, rechargeable battery; internal air pump that draws air through its water proof membrane on the back of the unit, across the sensors and exits through its one way valve on the bottom; LoRaWan antenna.

### DESCRIPTION

The present portable communication relay is part of a data collection and communication ecosystem. When deployed during a wildfire or other emergency, the relay operates as a portable, solar-powered, communication and weather station that gathers real-time weather and atmospheric data and sends it to the cloud such that it can be seen in real-time on a dashboard at an incident command post. It additionally functions as a communication link for all resources in a system using a series of IoT wearable devices.

In one aspect, the portable relay comprises three independent printed circuit boards (“pcbs”), where the circuit boards plug (i.e, fit together to form an electrical connection) into each other to form the relay. For this aspect: PCB #1 (25)—which can also be used independently to be placed on an emergency responder (e.g., firefighter) with a modified enclosure to be used as a wearable tracking unit—is the communication platform, which includes GPS, Cellular, CO2 sensor, Air Temp sensor, and LoraWan; PCB #2 (26) is the weather station and includes, for instance, humidity and barometric pressure sensors; PCB #3 (27) is the wind sensor, which includes ultrasonic wind sensors. The relay transfers data to the cloud in two distinct ways. First, it produces its own data and sends it to the cloud with the GPS location of the relay. Second, it collects and transmits data to the cloud that is collected by devices worn by emergency personnel.

The communication relay is a modular system. It is used in conjunction with wearable IoT units. Either the Hub or Tracker transmits realtime data on emergency incidents such as during wildfires. The data is seen in realtime at incident command stations to provide emergency managers operational intelligence to monitor emergency provider location and improved incident operations. The three PCBs are installed in an enclosure that has several louvers at the top to allow passive airflow over the interior where all sensors are located, with the exception of ultrasonic wind sensors (22). The ultrasonic wind sensors (22) are installed on the bottom of the enclosure pointing down toward a plate that measures wind speed and direction.

The present invention offers many advantages. It is the only hardware technology designed to monitor multiple emergency providers (e.g., firefighters) with respect to location, environmental and atmospheric conditions on a single dashboard in realtime. It can also include all resources on a single incident form from multiple agencies, whether it is a State, Federal, local or volunteer agency. It can also include non-emergency personnel (e.g., non-firefighter personnel) such as utility workers, law enforcement and civilians. Non-human resources such as vehicle and aircraft can also be plugged into the system.

1. A system for communication of information related to emergency situations, wherein the system comprises a first printed circuit board, a second printed circuit board and a third printed circuit board, and wherein the first printed circuit board, the second printed circuit board and the third printed circuit board plug into each other to form a communication relay.

2. The system of claim 1, wherein the first printed circuit board is a communication platform comprising GPS, Cellular, a CO₂ sensor, and Air Temp sensor and LoraWan.

3. The system of claim 1, wherein the second printed circuit board is a weather station comprising humidity and barometric pressure sensors.

4. The system of claim 1, wherein the third printed circuit board is a wind sensor comprising ultrasonic wind sensors.

5. The system of claim 2, wherein the second printed circuit board is a weather station comprising humidity and barometric pressure sensors, and wherein the third printed circuit board is a wind sensor comprising ultrasonic wind sensors.
